(19) United States
(12) Patent Application Publication
(10) Pub. No.: US 2016/0081217 A1
(43) Pub. Date: Mar. 17, 2016

(54) CONFIRM PROPER SEATING OF A DUAL INLINE MEMORY MODULE

(71) Applicant: HEWLETT-PACKARD DEVELOPMENT COMPANY, L.P., Houston, TX (US)

(72) Inventors: John Norton, Houston, TX (US); Timothy Keef, Houston, TX (US)

(21) Appl. No.: 14/787,458

(22) PCT Filed: Jun. 18, 2013
(86) PCT No.: PCT/US2013/046401

§ 371 Date: Oct. 27, 2015

(51) Int. Cl. H05K 7/14; G11C 29/00

(52) U.S. Cl. CPC H05K 7/1488; G11C 29/00

(57) ABSTRACT

A server system includes a dual in-line memory module, a dual inline memory module baffle, a hood, and a chassis. The dual inline memory module baffle includes a set of dual inline memory module engagement members. The hood includes a first set of hood engagement members. The chassis includes a first set of chassis engagement members and a second set of chassis engagement members.

### BACKGROUND

A server system responds to requests across a computer network to provide, or help provide, a network service. A server system may operate within a client-server architecture and run computer programs to serve requests and/or perform some task on behalf of clients. A server system may include a removable dual inline memory module (DIMM) and a corresponding DIMM socket to receive the removable DIMM. The DIMM may include dynamic random-access memory integrated circuits mounted on a printed circuit board.

### BRIEF DESCRIPTION OF THE DRAWINGS

Non-limiting examples are described in the following description, read with reference to the figures attached hereto and do not limit the scope of the claims. Dimensions of components and features illustrated in the figures are chosen primarily for convenience and clarity of presentation and are not necessarily to scale. Referring to the attached figures:

FIG. 1 is a block diagram illustrating a server system according to an example.

FIG. 2A is a perspective view illustrating a dual inline memory module (DIMM), a DIMM socket, and a chassis of a server system according to an example.

FIG. 2B is a perspective view illustrating the DIMM, the DIMM socket, the chassis, and a DIMM baffle of the server system of FIG. 2A according to an example.

FIG. 2C is a perspective view illustrating the DIMM, the DIMM socket, the chassis, the DIMM baffle, and a hood of the server system of FIG. 2B according to an example.

FIG. 3A is a side view illustrating the server system of FIG. 2C in a seated DIMM state according to an example.

FIG. 3B is a side view illustrating the server system of FIG. 2C in an unseated DIMM state according to an example.

FIG. 4 is a perspective view illustrating the DIMM baffle of the server system of FIG. 2C according to an example.

FIG. 5 is a perspective view illustrating the hood of the server system of FIG. 2C according to an example.

FIG. 6 is a perspective view illustrating the chassis of the server system of FIG. 2C according to an example.

FIG. 7 is a flowchart illustrating a method of confirming a DIMM unseated in a DIMM socket according to an example.

### DETAILED DESCRIPTION

A server system responds to requests across a computer network to provide, or help provide, a network service. The server system may operate within a client-server architecture and run computer programs to serve requests and/or perform some task on behalf of clients. Typical computing servers are database servers, file servers, mail servers, print servers, web servers, gaming servers, application servers, or other servers. The server system may include a removable dual inline memory module (DIMM) including dynamic random-access memory integrated circuits mounted on a printed circuit board. The server system may also include a corresponding DIMM socket to receive the removable DIMM. The DIMM and/or corresponding DIMM socket may have features to enable proper engagement with each other. Periodically, however, the DIMM may be unseated in the DIMM socket. That is, the unseated DIMM is not be properly installed in the DIMM socket. Such an unidentified unseated DIMM may cause server system failures, service technician requests, extended system downtime, and the like.

In examples, a server system includes a DIMM, a DIMM baffle, a hood, and a chassis. The DIMM engages a DIMM socket. The DIMM baffle includes a set of DIMM engagement members. The DIMM baffle contacts and at least partially encloses the DIMM. The hood at least partially covers the DIMM baffle. The hood includes a first set of hood engagement members. The chassis receives the DIMM baffle and the hood. The chassis includes a first set of chassis engagement members and a second set of chassis engagement members. The first set of chassis engagement members may engage and guide the DIMM engagement members to a DIMM aligned position in response to the contact between the DIMM baffle and the DIMM seated in the DIMM socket. The second set of chassis engagement members may engage and guide the first set of hood engagement members to a hood aligned position in response to the contact between the DIMM baffle and the DIMM seated in the DIMM socket.

Further, the first set of chassis engagement members is configured to prevent guiding the DIMM engagement members to the DIMM aligned position in response to the contact between the DIMM baffle and the DIMM unseated in the DIMM socket. Also, the second set of chassis engagement members is configured to prevent guiding the first set of hood engagement members to the hood aligned position in response to the contact between the DIMM baffle and the DIMM unseated in the DIMM socket. Consequently, the hood would not be able to be properly installed if the DIMM is unseated. Thus, the inability of the hood to be properly installed provides mechanical feedback to an installer that the DIMM is unseated and needs to be reseated. Accordingly, identification of an initially unseated DIMM may be identified at the time of installation and quickly corrected by a proper reinstallation. Thus, identification and correction of an initially unseated DIMM may reduce server system failures, service technician requests, long delays, and the like.

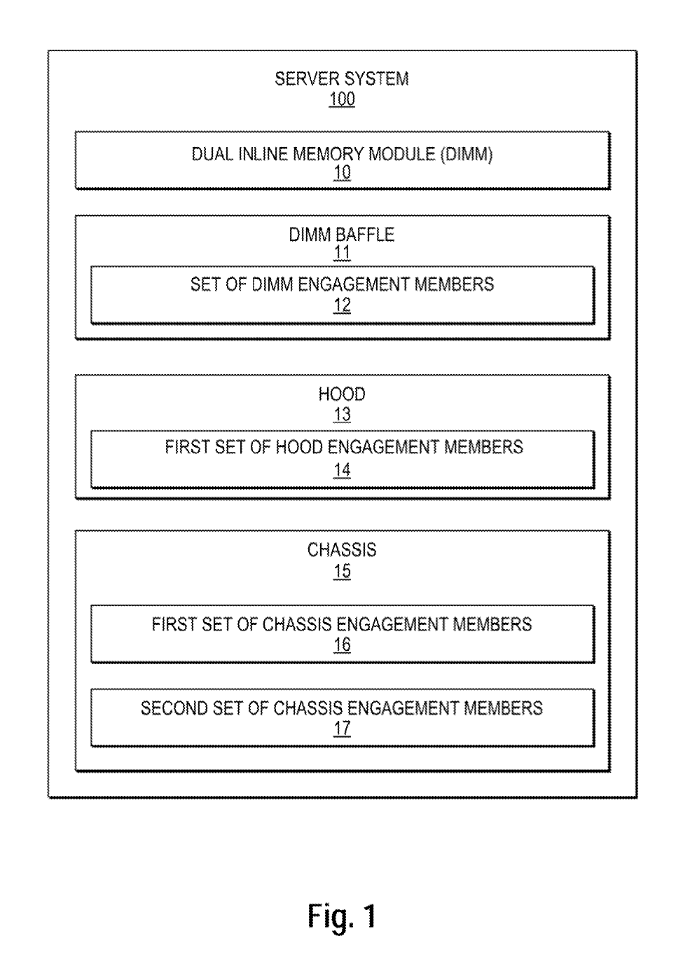

FIG. 1 is a block diagram illustrating a server system according to an example. Referring to FIG. 1, in some examples, a server system 100 includes a DIMM 10, a DIMM baffle 11, a hood 13, and a chassis 15. The DIMM 10 engages a DIMM socket. The DIMM baffle 11 includes a set of DIMM engagement members 12. The DIMM baffle 11 contacts and at least partially encloses the DIMM 10. For example, a surface of the DIMM baffle 11 may be placed in contact with and rest on a surface of the DIMM 10. The DIMM baffle 11 may at least partially enclose the DIMM 10 to reduce an amount of air that comes in contact with the DIMM 10. The DIMM baffle 11 may also redirect an amount of air to other components of the server system 100. In some examples, the DIMM baffle 11 may at least partially enclose and rest on a plurality of DIMMS 10 disposed in a DIMM bank.

Referring to FIG. 1, in some examples, the hood 13 may connect to the chassis 15 and cover an interior space formed by the chassis 15. For example, the hood 13 may at least partially cover the DIMM baffle 11 disposed within the interior space. The hood 13 includes a first set of hood engagement members 14. The chassis 15 receives the DIMM baffle 11 and the hood 13. The chassis 15 includes a first set of chassis engagement members 16 and a second set of chassis engagement members 17.

Referring to FIG. 1, in some examples, the first set of chassis engagement members 16 engages and guides the DIMM engagement members 12 to a DIMM aligned position in response to the contact between the DIMM baffle and the DIMM seated in the DIMM socket. For example, the DIMM aligned position includes the DIMM engagement members 12 placed at respective DIMM arrival positions within the first set of chassis engagement members 16. The second set of chassis engagement members 17 engages and guides the first set of hood engagement members 14 in a hood aligned position in response to the contact between the DIMM baffle and the DIMM seated in the DIMM socket. For example, the hood aligned position includes the first set of hood engagement members 14 placed at respective hood arrival positions within the second set of chassis engagement members 17.

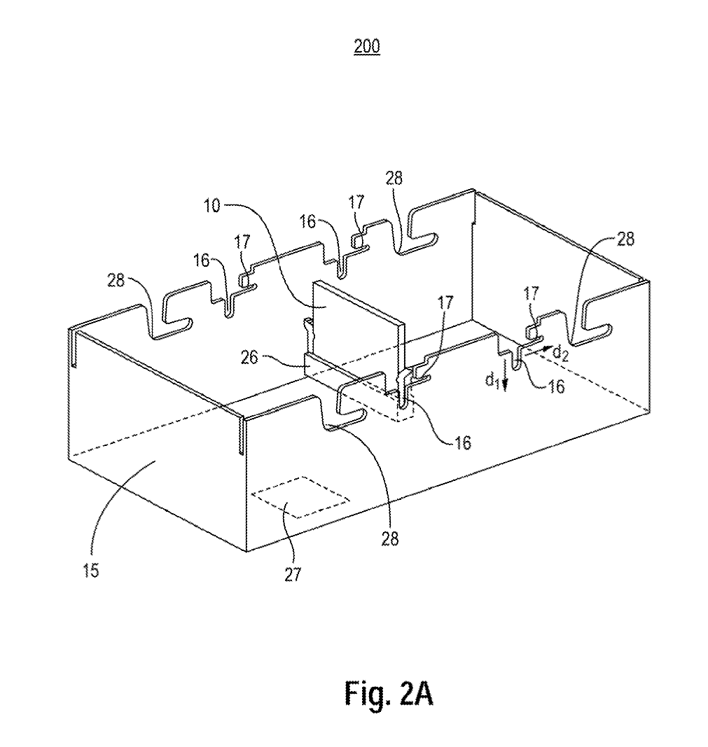

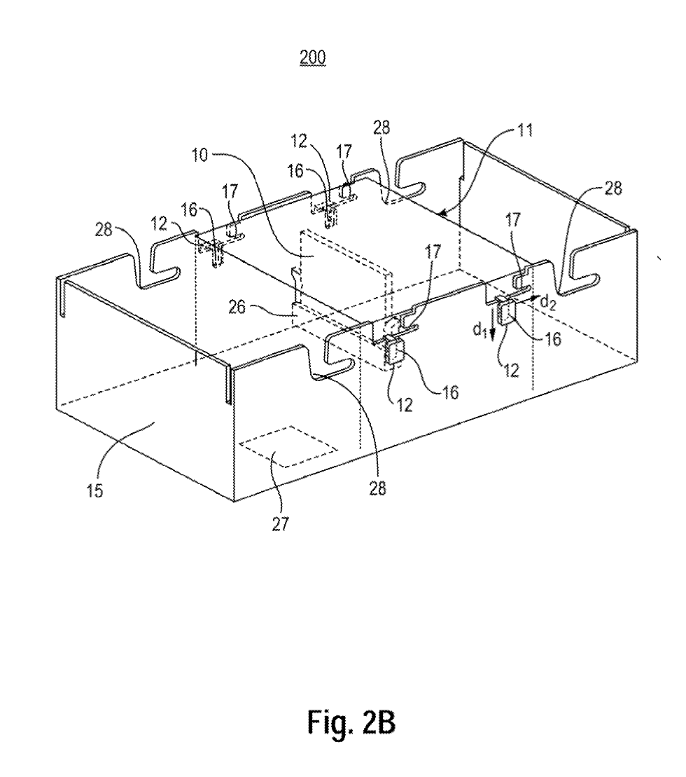

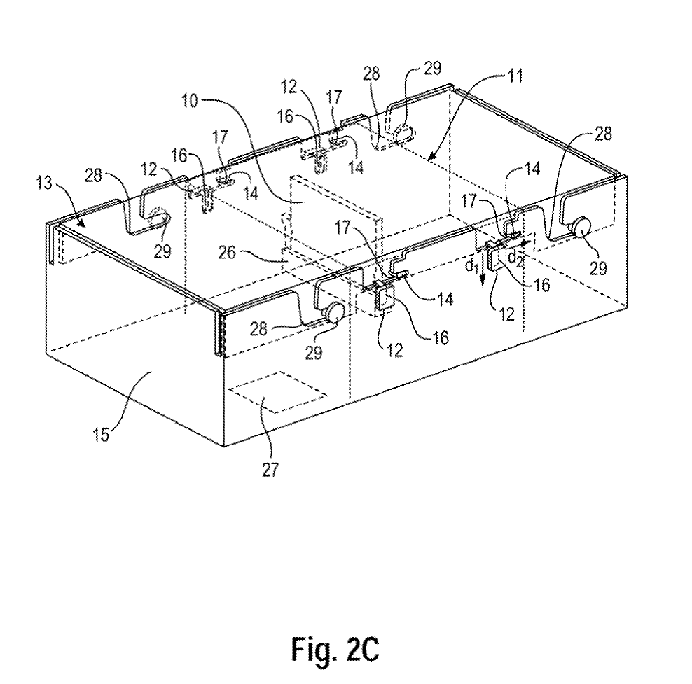

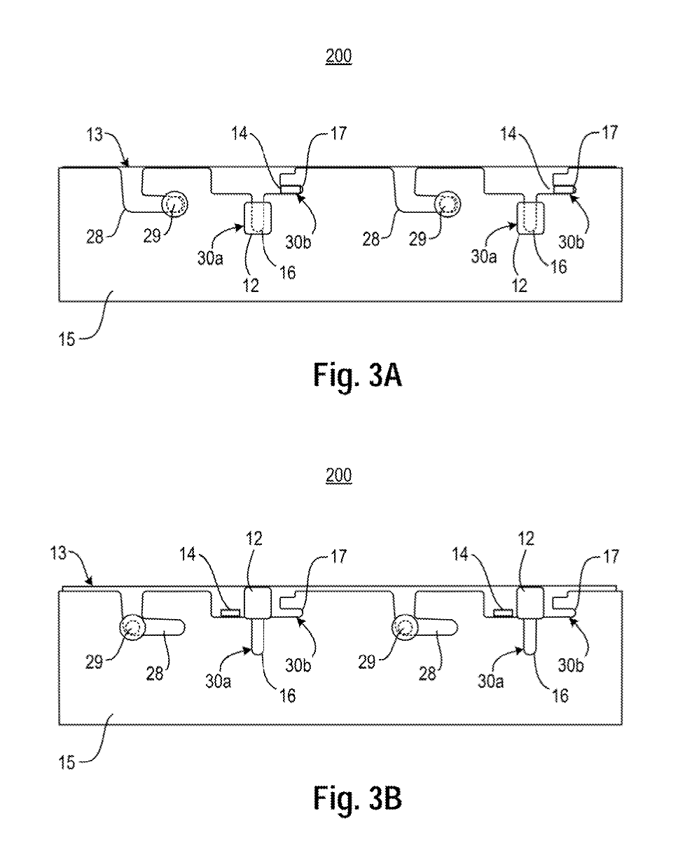

FIG. 2A is a perspective view illustrating a DIMM, a DIMM socket, and a chassis of a server system according to an example. FIG. 2B is a perspective view illustrating the DIMM, the DIMM socket, the chassis, and a DIMM baffle of the server system of FIG. 2A according to an example. FIG. 2C is a perspective view illustrating the DIMM, the DIMM socket, the chassis, the DIMM baffle, and a hood of the server system of FIG. 2B according to an example. FIG. 3A is a side view illustrating the server system of FIG. 2C in a seated DIMM state according to an example. FIG. 3B is a side view illustrating the server system of FIG. 2C in an unseated DIMM state according to an example. Referring to FIGS. 2A-3B, in some examples, a server system 200 includes the DIMM 10, the DIMM baffle 11, the hood 13, and the chassis 15 as previously discussed with respect to the server system 100 of FIG. 1.

Referring to FIGS. 2A-3B, in some examples, the server system 200 includes a DIMM 10 to engage a corresponding DIMM socket 26. The DIMM 10 and/or DIMM socket 26 may include features to removable connect to each other. For example, the DIMM socket 26 may include latches and the DIMM 10 may include recesses. The DIMM baffle 11 may at least partially enclose the DIMM 10, for example, to restrict an amount of air flow that contacts the DIMM 10 and redirect an amount of air flow to other components 27 of the server system 200. For example, the other components 27 may include a central processing unit (CPU), and the like. The DIMM baffle 11 may also be placed in contact with the DIMM 10. For example, a surface of the DIMM baffle 11 may be placed in contact with and rest on a surface of the DIMM 10.

That is, an under side of a top portion of the DIMM baffle 11 may rest on an edge surface of the DIMM 10. The contact between the DIMM baffle 11 and the DIMM 10, positions the DIMM baffle 11 in a manner to either allow, or not allow, sufficient clearance above it for a hood 13 to be properly installed to the chassis 15 based on whether the DIMM is seated (e.g., properly installed in the DIMM socket) or unseated (e.g., not properly installed in the DIMM socket). The DIMM baffle 11 may include a set of DIMM engagement members 12. In some examples, the respective DIMM engagement members 12 may be disposed at a front and back of the DIMM baffle 11 and in line with respective ends of the DIMM socket 26 where displacement of an unseated DIMM may be maximized. In some examples, the DIMM baffle 11 may at least partially enclose and rest on a plurality of DIMMS 10 disposed in a DIMM bank.

Referring to FIGS. 2A-3B, in some examples, when the DIMM 10 is seated in the corresponding DIMM socket 26, the DIMM baffle 11 may rest on the DIMM 10 and allow sufficient clearance above the DIMM baffle 11 for the hood 13 including a first set of hood engagement members 14 to properly connect to the chassis 15 resulting in a seated DIMM state. For example, the DIMM engagement members 12 may be guided along the first set of chassis engagement members 16 to respective DIMM arrival positions 30a (FIG. 3A). In some examples, the hood 13 may connect to the chassis 15 and cover an interior space formed by the chassis 15. For example, the hood 13 may at least partially cover the DIMM baffle 11. The hood 13 may also include a second set of hood engagement members 29.

Alternatively, when the DIMM 10 is unseated in the corresponding DIMM socket 26, the DIMM baffle 11 may rest on the DIMM 10 and not allow sufficient clearance above the DIMM baffle 11 for the hood 13 to properly connect to the chassis 15. That is, the DIMM baffle 11 may be elevated above its normal position with respect to the chassis 15 and interfere with (e.g., contact) the hood 13 to prevent the hood 13 from properly connecting to the chassis 15 resulting in an unseated DIMM state. For example, the DIMM engagement members 12 may not arrive at the respective DIMM arrival positions 30a due to the DIMM baffle 11 resting in an elevated position due to contact with the unseated DIMM (FIG. 3B).

Referring to FIGS. 2A-3B, in some examples, the chassis 15 receives the DIMM baffle 11 and the hood 13. In some examples, the chassis 15 includes a first set of chassis engagement members 16, a second set of chassis engagement members 17, and a third set of chassis engagement members 28. The first set of chassis engagement members 16 engages and guides the DIMM engagement members 12 to a DIMM aligned position in response to the contact between the DIMM baffle and the DIMM seated in the DIMM socket. For example, the DIMM aligned position corresponds to the DIMM engagement members 12 placed at respective DIMM arrival positions 30a within the first set of chassis engagement members 16. (FIG. 3A).

The second set of chassis engagement members 17 engages and guides the first set of hood engagement members 14 to a hood aligned position in response to the contact between the DIMM baffle and the DIMM seated in the DIMM socket. For example, the hood aligned position corresponds to the first set of hood engagement members 14 placed at respective hood arrival positions 30b within the second set of chassis engagement members 17. The first set of hood engagement members 14 is guided along the second set of chassis engagement members 17 to the respective hood arrival positions 30b (FIG. 3B). The set of DIMM engagement members 12 is at the respective DIMM arrival positions 30a and, thus, out of the respective paths of the first set of hood engagement members 14 to reach the respective hood arrival positions 30b (FIG. 38). In some examples, the third set of chassis engagement members 28 engages the second set of hood engagement members 29 to secure the hood 13 to the chassis 15 when the hood 13 is in the hood aligned position.

Referring to FIGS. 2A-3B, in some examples, the first set of chassis engagement members 16 is configured to prevent guiding the DIMM engagement members 12 to the DIMM aligned position in response to the contact between the DIMM baffle and the DIMM unseated in the DIMM socket. That is, the DIMM engagement members 12 may not arrive at the respective DIMM arrival positions 30a due to the DIMM baffle 11 resting in an elevated position due to contact with the unseated DIMM (FIG. 3B). Additionally, the second set of chassis engagement members 17 is configured to prevent guiding the first set of hood engagement members 14 to the hood aligned position in response to the contact between the DIMM baffle and the DIMM unseated in the DIMM socket.

For example, a respective DIMM engagement member of the set of DIMM engagement members 12 may block a respective one of the first set of hood engagement members 14 from arriving at the respective hood arrival position 30b in response the contact between the DIMM baffle and the DIMM unseated in the DIMM socket. That is, the first set of hood engagement members 14 may not reach the respective hood arrival position 30b due to the at least one respective path to the respective hood arrival position 30b being blocked by the respective DIMM engagement member 12 (FIG. 3B).

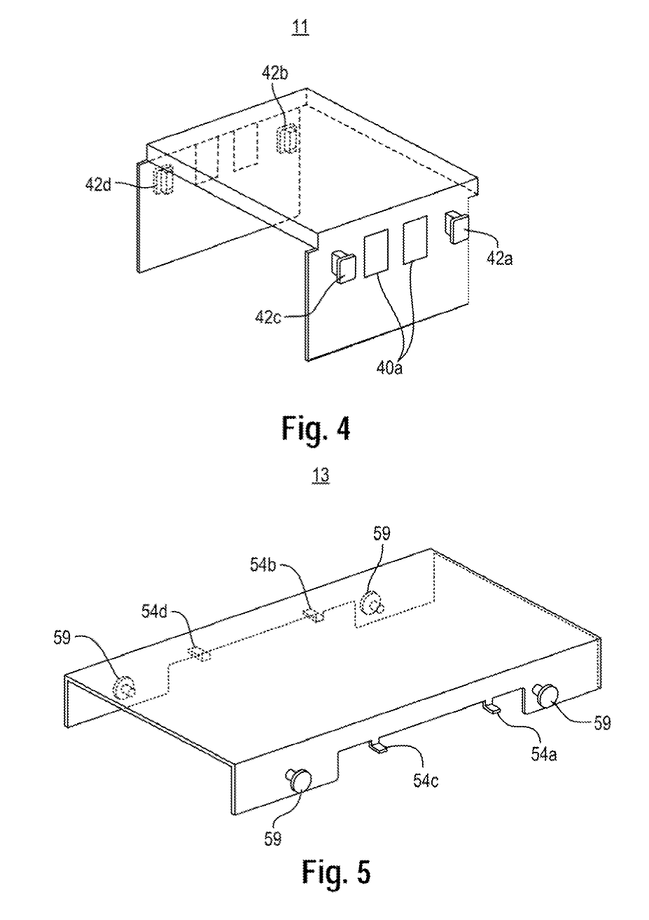

FIG. 4 is a perspective view illustrating the DIMM baffle of the server system of FIG. 2C according to an example. Referring to FIG. 4, in some examples, a set of DIMM engagement members 12 (FIGS. 1-3B) of the DIMM baffle 11 includes a first tab member 42a, a second tab member 42b, a third tab member 42c, and a fourth tab member 42d. For example, the first tab member 42a and the third tab 42c member may be disposed on one end of the DIMM baffle 11 to extend outward therefrom. Additionally, the second tab member 42b and the fourth tab member 42d may be disposed on an other end of the DIMM baffle 11 to extend outward therefrom. The DIMM baffle 11 may also include holes 40a to enable a flow of air to pass there through.

FIG. 5 is a perspective view illustrating the hood of the server system of FIG. 2C according to an example. Referring to FIG. 5, in some examples, a first set of hood engagement members 14 (FIGS. 1-3B) of the hood 13 may include a first hood projection member 54a, a second hood projection member 54b, a third hood projection member 54c, and a fourth hood projection member 54d. For example, the first hood projection member 54a and the third hood projection member 54c may be disposed on one end of the hood 13 to extend outward therefrom. Additionally, the second hood projection member 54b and the fourth hood projection member 54d may be disposed on an other end of the hood 13 to extend outward therefrom. In some examples, the second set of hook engagement members 29 of the hood 13 includes a plurality of post members 59. Several of the post members 59 may be on different ends of the hood 13 and extend outward therefrom.

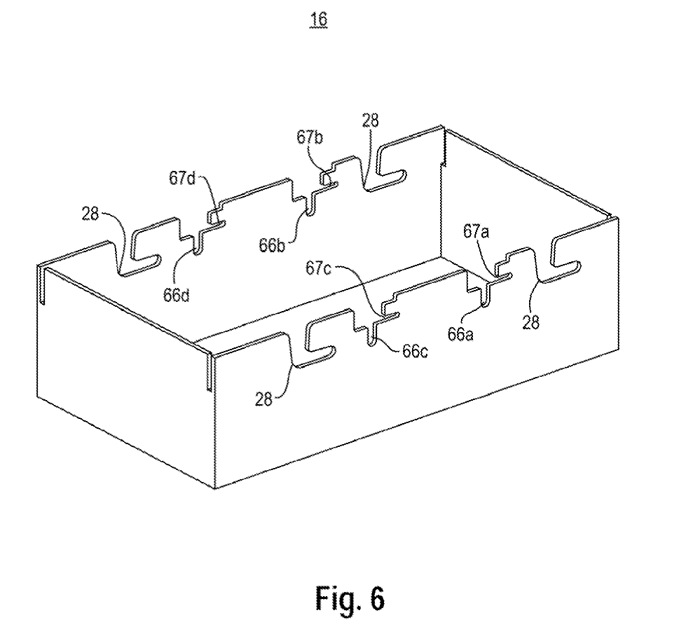

FIG. 6 is a perspective view illustrating the chassis of the server system of FIG. 2C according to an example. Referring to FIG. 6, in some examples, the first set of chassis engagement members 16 (FIGS. 1-3B) of the chassis 15 includes a first slot member 66a, a second slot member 66b, a third slot member 66c, and a fourth slot member 66d. For example, the first slot member 66a and the third slot member 66c may be disposed on one end of the chassis 15. Additionally, the second slot member 66b and the fourth slot member 66d may be disposed on an other end of the chassis 15. In some examples, each one of the first slot member 66a, the second slot member 66b, the third slot member 66c, and the fourth slot member 66d may receive a respective DIMM engagement member such as a respective tab member 42a, 42b, 42c, and 42d, for example, in a first direction d₁.

Referring to FIG. 6, in some examples, the second set of chassis engagement members 17 (FIGS. 1-38) includes a first channel member 67a, a second channel member 67b, a third channel member 67c, and a fourth channel member 67d. For example, the first channel member 67a and the third channel member 67c may be disposed on one end of the chassis 15. Additionally, the second channel member 67b and the fourth channel member 67d may be disposed on the other end of the chassis 15.

For example, each one of the first channel member 67a, the second channel member 67b, the third channel member 67c, and the fourth channel member 67d is configured to receive a respective one of the first set of hood engagement members such as a respective hood projection member 54a, 54b, 54c, and 54d, for example, in a second direction d₂. In some examples, the first direction d₁ is substantially perpendicular to the second direction d₂. In some examples, the third set of chassis engagement members 28 (FIGS. 2A-3B) includes a plurality of openings 68. For example, the openings 68 are configured to receive the post members 59, respectively, to secure the hood 13 to the chassis 15 when the hood 13 is in the hood aligned position and properly installed.

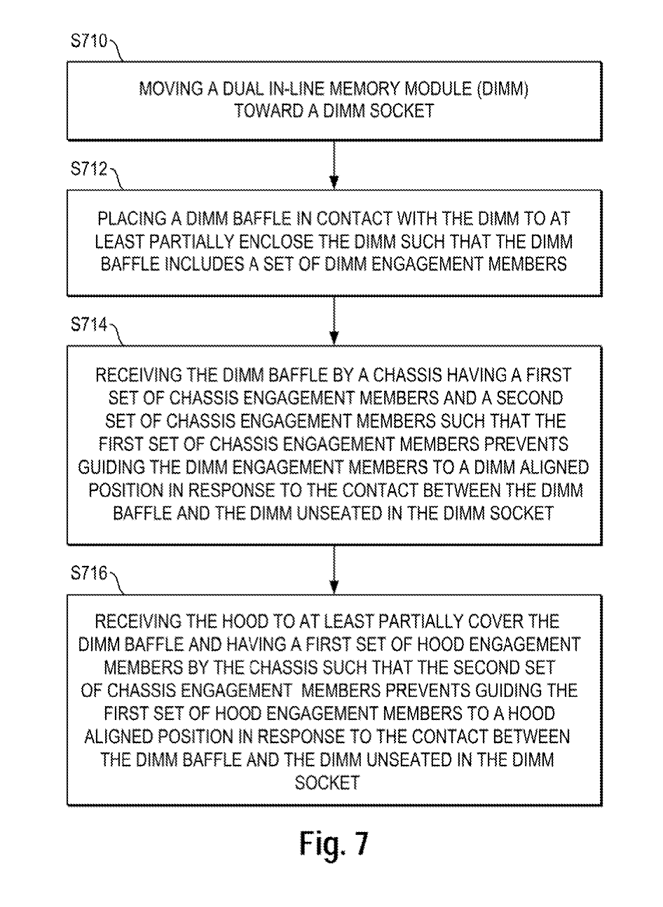

FIG. 7 is a flowchart illustrating a method of confirming a dual in-line memory module unseated in a dual in-line memory module socket according to an example. Referring to FIG. 7, in block S710, a DIMM is moved toward a DIMM socket. For example, the DIMM is inserted into the DIMM socket. In block S712, a DIMM baffle is placed in contact with the DIMM to at least partially enclose the DIMM. That is, an under side of a top portion of the DIMM baffle may rest on an edge surface of DIMM. That is, a respective edge of the DIMM opposite to the edge inserted into the DIMM socket 26 contacts the DIMM baffle. The DIMM baffle includes a set of DIMM engagement members.

In block S714, a chassis having a first set of chassis engagement members and a second set of chassis engagement members receives the DIMM baffle. The first set of chassis engagement members prevents guiding the DIMM engagement members in a DIMM aligned position in response to the contact between the DIMM baffle and the DIMM unseated in the DIMM socket. In block S716, the chassis receives the hood to at least partially cover the DIMM baffle. The hood includes a first set of hood engagement members. The second set of chassis engagement members prevents guiding the first set of hood engagement members in a hood aligned position in response to the contact between the DIMM baffle and the DIMM unseated in the DIMM socket.

In some examples, the second set of chassis engagement members prevents guiding the first set of hood engagement members to a hood aligned position in response to contact between the DIMM baffle and the DIMM unseated in the DIMM socket may also include blocking a respective one of a first set of hood engagement members from arriving at a respective hood arrival position by a respective DIMM engagement member. The blocking the respective one of the first set of hood engagement members by the respective DIMM engagement member is in response to the contact between the DIMM baffle and the DIMM unseated in the DIMM socket.

In some examples, receiving the DIMM baffle by a chassis having a first set of chassis engagement members and a second set of chassis engagement members may also include engaging and guiding the DIMM engagement members to a DIMM aligned position by the first set of chassis engagement members in response to the contact between the DIMM baffle and the DIMM seated in the DIMM socket. In some examples, receiving the DIMM baffle by a chassis having a first set of chassis engagement members and a second set of chassis engagement members may also include engaging and guiding the first set of hood engagement members to a hood aligned position by the second set of chassis engagement members in response to the contact between the DIMM baffle and the DIMM seated in the DIMM socket.

It is to be understood that the flowchart of FIG. 7 illustrates architecture, functionality, and/or operation of examples of the present disclosure. If embodied in software, each block may represent a module, segment, or portion of code that includes one or more executable instructions to implement the specified logical function(s). If embodied in hardware, each block may represent a circuit or a number of interconnected circuits to implement the specified logical function(s). Although the flowchart of FIG. 7 illustrates a specific order of execution, the order of execution may differ from that which is depicted. For example, the order of execution of two or more blocks may be rearranged relative to the order illustrated. Also, two or more blocks illustrated in succession in FIG. 7 may be executed concurrently or with partial concurrence. All such variations are within the scope of the present disclosure.

The present disclosure has been described using non-limiting detailed descriptions of examples thereof that are not intended to limit the scope of the general inventive concept. It should be understood that features and/or operations described with respect to one example may be used with other examples and that not all examples have all of the features and/or operations illustrated in a particular figure or described with respect to one of the examples. Variations of examples described will occur to persons of the art. Furthermore, the terms “comprise,” “include,” “have” and their conjugates, shall mean, when used in the disclosure and/or claims, “including but not necessarily limited to.”

It is noted that some of the above described examples may include structure, acts or details of structures and acts that may not be essential to the general inventive concept and which are described for illustrative purposes. Structure and acts described herein are replaceable by equivalents, which perform the same function, even if the structure or acts are different, as known in the art. Therefore, the scope of the general inventive concept is limited only by the elements and limitations as used in the claims.

What is claimed is:

1. A server system, comprising:
a dual in-line memory module (DIMM) to engage a DIMM socket;
a DIMM baffle to contact and at least partially enclose the DIMM, the DIMM baffle including a set of DIMM engagement members;
a hood to at least partially cover the DIMM baffle, the hood including a first set of hood engagement members; and
a chassis to receive the DIMM baffle and the hood, the chassis including a first set of chassis engagement members and a second set of chassis engagement members;
the first set of chassis engagement members to engage and guide the DIMM engagement members to a DIMM aligned position in response to the contact between the DIMM baffle and the DIMM seated in the DIMM socket; and
the second set of chassis engagement members to engage and guide the first set of hood engagement members to a hood aligned position in response to the contact between the DIMM baffle and the DIMM seated in the DIMM socket.

2. The server system of claim 1, wherein the first set of chassis engagement members is configured to prevent guiding the DIMM engagement members to the DIMM aligned position in response to the contact between the DIMM baffle and the DIMM unseated in the DIMM socket.

3. The server system of claim 2, wherein the second set of chassis engagement members is configured to prevent guiding the first set of hood engagement members to the hood aligned position in response to the contact between the DIMM baffle and the DIMM unseated in the DIMM socket.

4. The server system of claim 3, wherein a respective DIMM engagement member of the set of DIMM engagement members is configured to block a respective one of the first set of hood engagement members from arriving at the hood aligned position in response to the contact between the DIMM baffle and the DIMM unseated in the DIMM socket.

5. The server system of claim 1, wherein the set of DIMM engagement members includes a first tab member and a third tab member on one end of the DIMM baffle to extend outward therefrom, and a second tab member and a fourth tab member on an other end of the DIMM baffle to extend outward therefrom.

6. The server system of claim 1, wherein the first set of hood engagement members includes a first hood projection member and a third hood projection member on one end of the hood to extend outward therefrom, and a second hood projection member and a fourth hood projection member on an other end of the hood to extend outward therefrom.

7. The server system of claim 1, wherein the first set of chassis engagement members includes a first slot member and a third slot member on one end of the chassis, and a second slot member and a fourth slot member on an other end of the chassis.

8. The server system of claim 7, wherein the second set of chassis engagement members includes a first channel member and a third channel member on one end of the chassis, and a second channel member and a fourth channel member on the other end of the chassis.

9. The server system of claim 8, wherein each one of the first slot member, the second slot member, the third slot member, and the fourth slot member is configured to receive a respective DIMM engagement member in a first direction.

10. The server system of claim 9, wherein each one of the first channel member, the second channel member, the third channel member, and the fourth channel member is configured to receive a respective one of the first set of hood engagement members in a second direction.

11. The server system of claim 10, wherein the first direction is substantially perpendicular to the second direction.

12. A method of confirming a dual in-line memory module unseated in a dual in-line memory module socket, the method comprising:
moving the dual in-line memory module (DIMM) toward the DIMM socket;
placing a DIMM baffle in contact with the DIMM to at least partially enclose the DIMM such that the DIMM baffle includes a set of DIMM engagement members;
receiving the DIMM baffle by a chassis having a first set of chassis engagement members and a second set of chassis engagement members such that the first set of chassis engagement members prevents guiding the DIMM engagement members to a DIMM aligned position in response to the contact between the DIMM baffle and the DIMM unseated in the DIMM socket; and
receiving the hood to at least partially cover the DIMM baffle and having a first set of hood engagement members by the chassis such that the second set of chassis engagement members prevents guiding the first set of hood engagement members to a hood aligned position in response to the contact between the DIMM baffle and the DIMM unseated in the DIMM socket.

13. The method according to claim 12, wherein the second set of chassis engagement members prevents guiding the first set of hood engagement members to a hood aligned position in response to contact between the DIMM baffle and the DIMM unseated in the DIMM socket further comprises:
blocking a respective one of the first set of hood engagement members from arriving at the hood aligned position by a respective DIMM engagement member of the set of DIMM engagement members in response to the contact between the DIMM baffle and the DIMM unseated in the DIMM socket.

14. The method according to claim 12, wherein the receiving the DIMM baffle by a chassis having a first set of chassis engagement members and a second set of chassis engagement members further comprises:
engaging and guiding the DIMM engagement members to a DIMM aligned position by the first set of chassis engagement members in response to the contact between the DIMM baffle and the DIMM seated in the DIMM socket.

15. The method according to claim 12, wherein the receiving the DIMM baffle by a chassis having a first set of chassis engagement members and a second set of chassis engagement members further comprises:
engaging and guiding the first set of hood engagement members to a hood aligned position by the second set of chassis engagement members in response to the contact between the DIMM baffle and the DIMM seated in the DIMM socket.
